(19) United States
(12) Patent Application Publication
(10) Pub. No.: US 2026/0143987 A1
(43) Pub. Date: May 21, 2026

(54) SEMICONDUCTOR STRUCTURE AND METHOD OF DICING THE SAME

(71) Applicant: WUHAN XINXIN SEMICONDUCTOR MANUFACTURING CO., LTD., Wuhan (CN)

(72) Inventors: Sheng HU, Wuhan (CN); Yongling MAO, Wuhan (CN); Shengjin SONG, Wuhan (CN)

(21) Appl. No.: 19/373,172

(22) Filed: Oct. 29, 2025

(30) Foreign Application Priority Data
Nov. 19, 2024 (CN) 202411657847.7

(51) Int. Cl. H01L 21/78; H01L 21/428; H01L 23/00; H01L 25/065

(52) U.S. Cl. CPC H10P 54/00; H10P 34/42; H10W 90/00; H10W 90/26; H10W 90/792

(57) ABSTRACT

A method of handling a test pad and a method of fabricating a semiconductor device are disclosed. The method of handling a test pad includes: providing a substrate formed thereon with a first insulating dielectric layer and a first test pad in the first insulating dielectric layer, wherein a surface of the first test pad is at least partially exposed from the first insulating dielectric layer, and there is a probe mark with a protrusion resulting from testing with probe tips on the surface portion of the first test pad exposed from the first insulating dielectric layer; and heating and melting the protrusion by laser annealing, thereby reducing a height of the protrusion. This invention can ensure good flatness of a surface to be bonded while enabling reduced process complexity and preventing metal contamination of the surface to be bonded.

### CROSS-REFERENCES TO RELATED APPLICATION

This application claims the priority of Chinese patent application number 202411657847.7, filed on Nov. 19, 2024, the entire contents of which are incorporated herein by reference.

### TECHNICAL FIELD

The present invention relates to the field of semiconductor manufacturing technology and, in particular, to a semiconductor structure and a method of dicing the same.

### BACKGROUND

As semiconductor technology steps into the post-Moore's law era, in order to meet the ever-increasing demand for a higher level of integration and higher performance, chip structures are developing toward three-dimensional (3D) integration. Stacking techniques can be used to vertically interconnect multiple dies together to increase the number of transistors per unit area multiple times, resulting in a much higher level of integration. Moreover, this can shorten the global wiring length, accelerate communication, speed up response and reduce energy consumption.

Vertically interconnecting multiple dies typically involves: forming multiple wafers using wafer-level semiconductor technology; stacking and bonding the wafers, forming an interconnected wafer stack; and dicing the wafer stack into individual die stacks. Hybrid bonding is a technique involving both bonding between metal electrodes and bonding between dielectric insulating layers, of different wafers. As micro-bumps are not necessary, even shorter interconnections can be attained. Therefore, hybrid bonding can achieve high-density integration and is considered indispensable for 3D packaging.

Wafer stacks from hybrid bonding are diced into individual stacked chip structures. Existing wafer dicing techniques mainly include mechanical grinding, laser dicing and plasma dicing. However, mechanical grinding is highly invasive and tends to cause fragmentation, cracking, notching or delamination of dielectric layers in wafers, which is detrimental to chip performance. Additionally, mechanical grinding is typically performed along dicing lanes with a large lateral width, which is not favorable to chip miniaturization. Further, particles produced during mechanical grinding would affect the cleanliness and flatness of chip surfaces. Laser dicing is conducted along narrower dicing lanes, but produces much heat which may cause material remelting. Even when a protective coating is applied to the wafer surface, slag particles will accumulate around upper edges of lane openings. Plasma dicing is limited in application and suffers from difficult selection of an appropriate etchant and adherence of etching byproducts to chip surfaces. Therefore, reliable dicing of a structure resulting from hybrid bonding remains an unsolved challenge for advanced 3D packaging technology.

### SUMMARY

It is an object of the present invention to overcome the problem of unsatisfactory conventional dicing of semiconductor structures by presenting a novel semiconductor structure and dicing method.

To this end, the present invention provides a semiconductor structure, which includes:
at least two substrates each including a backing layer and a dielectric layer on the backing layer, wherein the semiconductor structure has blank regions, the blank regions do not include metal, in the blank regions, at least two of the backing layers have been modified with laser radiation, and wherein each adjacent two of laser-modified backing layers are spaced apart by the dielectric layer.

Optionally, in the semiconductor structure, the dielectric layers are not modified with laser radiation.

Optionally, in the semiconductor structure, each of the at least two substrates has device regions and dicing lanes between the device regions, the dicing lanes including blank sub-regions, wherein projections of the blank sub-regions on one of the at least two substrates have an overlap, and portions of the blank sub-regions of the at least two substrates corresponding to the overlap provide the blank regions of the semiconductor structure.

Optionally, in the semiconductor structure, the dicing lanes of each substrate have a width between 10 μm and 100 μm.

Optionally, in the semiconductor structure, the blank regions have a width between 0.5 μm and 100 μm.

Optionally, in the semiconductor structure, the semiconductor structure is a wafer stack separable into chip stacks.

Optionally, in the semiconductor structure, the number of the substrates in the semiconductor structure ranges from 2 to 16.

Optionally, in the semiconductor structure, the semiconductor structure has a thickness between 10 μm and 400 μm.

Optionally, in the semiconductor structure, the semiconductor structure includes a first substrate, a second substrate, a third substrate and a fourth substrate which are sequentially stacked, the first substrate including a first backing layer and a first dielectric layer on the first backing layer, the second substrate including a second backing layer and a second dielectric layer on the second backing layer, the third substrate including a third backing layer and a third dielectric layer on the third backing layer, the fourth substrate including a fourth backing layer and a fourth dielectric layer on the fourth backing layer.

Optionally, in the semiconductor structure, the first backing layer and the second backing layer are spaced apart by the first dielectric layer.

Optionally, in the semiconductor structure, the first backing layer and the second backing layer are spaced apart by the second dielectric layer.

Optionally, in the semiconductor structure, the first backing layer and the second backing layer are spaced apart by both of the first dielectric layer and the second dielectric layer.

Optionally, in the semiconductor structure, the first substrate has first device regions and first dicing lanes between adjacent first device regions, the first dicing lanes contain first blank sub-regions that do not include metal; the second substrate has second device regions and second dicing lanes between adjacent second device regions, the second dicing lanes contain second blank sub-regions that do not include metal; the third substrate has third device regions and third dicing lanes between adjacent third device regions, the third dicing lanes contain third blank sub-regions that do not include metal; the fourth substrate has fourth device regions and fourth dicing lanes between adjacent fourth device regions, the fourth dicing lanes contain fourth blank sub-regions that do not include metal; the first substrate, the second substrate, the third substrate and the fourth substrate are sequentially bonded together in a direction in which projections of the first blank sub-regions, the second blank sub-regions, the third blank sub-regions and the fourth blank sub-regions on the first substrate, the second substrate, the third substrate or the fourth substrate have an overlap.

Optionally, in the semiconductor structure, the projections of the first blank sub-regions, the second blank sub-regions, the third blank sub-regions and the fourth blank sub-regions on the first substrate exactly coincide.

Optionally, in the semiconductor structure, the projections of the first blank sub-regions, the second blank sub-regions, the third blank sub-regions and the fourth blank sub-regions on the first substrate partially overlap.

Optionally, in the semiconductor structure, the second blank sub-regions are as wide as the first blank sub-regions, and in the direction of bonding, the projections of the second blank sub-regions on the first substrate encompass part of the first blank sub-regions and part of the first substrate outside the first blank sub-regions.

The present invention also provides a method of dicing a semiconductor structure, which includes:
providing a semiconductor structure including at least two substrates each including a backing layer and a dielectric layer on the backing layer, the semiconductor structure having blank regions, the blank regions do not include metal; and
performing a stealth laser dicing process to modify at least two of the backing layers of the at least two substrates in the blank regions with laser radiation, wherein each adjacent two of laser-modified backing layers are spaced apart by the dielectric layer.

Optionally, in the method of dicing a semiconductor structure, after the backing layer in the blank regions of each of the at least two substrates is modified in the stealth laser dicing process, the method further including separating the semiconductor structure into individual devices by applying an external force to the semiconductor structure.

Optionally, in the method of dicing a semiconductor structure, separating the semiconductor structure into the individual devices by applying the external force to the semiconductor structure includes: under the action of the external force, separating each laser-modified backing layer of the substrate at its modified portions and separating each dielectric layer between adjacent laser-modified backing layers at both sides, resulting in the separation of the semiconductor structure into the individual devices.

Optionally, the method of dicing a semiconductor structure may further include: before the backing layer in the blank regions of each of the at least two substrates is modified in the stealth laser dicing process, placing the semiconductor structure on a carrier tape; and after the backing layer in the blank regions of each of the at least two substrates is modified in the stealth laser dicing process, stretching the carrier tape to apply the external force to the semiconductor structure.

The present invention provides a semiconductor structure and a method of dicing it. In the semiconductor structure, metal-free blank regions are formed and can be modified by a stealth dicing process, allowing the semiconductor structure to be subsequently easily separated into individual chips. Stealth dicing uses IR laser radiation and has the advantages of less invasiveness and less chip contamination, but cannot be used to dice a dicing lane with metal. In contrast, according to the present invention, extremely desirable dicing performance can be achieved by the stealth dicing process on the blank regions of the semiconductor structure.

### BRIEF DESCRIPTION OF THE DRAWINGS

FIG. 1 is a schematic illustration of a semiconductor structure according to an embodiment of the present invention.

FIG. 2 is a schematic illustration of modification of blank regions of a semiconductor structure by a stealth dicing process according to an embodiment of the present invention.

FIG. 3 is another schematic illustration of modification of blank regions of a semiconductor structure by a stealth dicing process according to an embodiment of the present invention.

FIG. 4 is yet another schematic illustration of modification of blank regions of a semiconductor structure by a stealth dicing process according to an embodiment of the present invention.

FIG. 5 is still yet another schematic illustration of modification of blank regions of a semiconductor structure by a stealth dicing process according to an embodiment of the present invention.

FIG. 6 schematically illustrates pre-stressing of a semiconductor structure according to an embodiment of the present invention.

FIG. 7 is a schematic illustration of an individual chip obtained in accordance with an embodiment of the present invention.

### LIST OF REFERENCE NUMERALS

10 semiconductor structure; 11 blank region; 20 carrier tape; 30 individual chip; 40 substrate; 40A device region; 40B dicing lane; 40C blank sub-region; 41 backing layer; 42 dielectric layer; 100 first substrate; 100A first device region; 100B first dicing lane; 100C first blank sub-region; 110 first backing layer; 120 first dielectric layer; 130 first conductive layer; 200 second substrate; 200A second device region; 200B second dicing lane; 200C second blank sub-region; 210 second backing layer; 220 second dielectric layer; 230 second conductive layer; 300 third substrate; 300A third device region; 300B third dicing lane; 300C third blank sub-region; 310 third backing layer; 320 third dielectric layer; 330 third conductive layer; 400 fourth substrate; 400A fourth device region; 400B fourth dicing lane; 400C fourth blank sub-region; 410 fourth backing layer; 420 fourth dielectric layer; 430 fourth conductive layer.

### Detailed Description

Semiconductor structures and dicing methods proposed herein will be described in greater detail below with reference to the accompanying drawings, which illustrate particular embodiments thereof. From the following description, advantages and features of the present invention will be more apparent. Note that the figure is provided in a very simplified form not necessarily drawn to exact scale for the only purpose of helping to explain the disclosed embodiments in a more convenient and clearer way.

The terminology used herein is for the purpose of describing particular embodiments only and is not intended to be limiting of the invention. Unless defined otherwise herein, all technical and scientific terms used herein have the same meaning as commonly understood by one of ordinary skill in the art to which the invention belongs. As used herein and in the appended claims, the terms “first,” “second,” and the like do not denote any order, quantity, or importance, but rather are used to distinguish one element from another. Likewise, the terms “a” and “an” do not denote a limitation of quantity, but rather denote the presence of at least one of the referenced item. The terms “plurality” or “several” means two or more than two. Unless defined otherwise herein, the terms “upper”, “overlying”, “lower”, “underlying” and/or the like are merely for ease of description, and should not be construed as being limited to a particular position, or to a particular spatial orientation. The use of “including” or “comprising” or the like herein is meant to encompass the elements or items listed thereafter and equivalents thereof but do not preclude the presence of other elements or items. The terms “connected”, “coupled” or the like are not restricted to physical or mechanical connections or couplings, and can include electrical connections or couplings, whether direct or indirect. As used herein and in the appended claims, the singular forms “a”, “an”, and the” are intended to include the plural forms as well, unless the context clearly indicates otherwise. It will be also understood that, as used herein, the term “and/or” includes any and all combinations of one or more of the associated listed items.

The present inventors have studied various available dicing techniques, in the pursuit of reliable dicing of a semiconductor structure with higher dicing performance into individual chips with high quality. Mechanical grinding uses a hard diamond grinding wheel rotating at a high speed to dice a wafer along dicing lanes into individual chips. Despite process simplicity and high efficiency, this technique may cause significant edge damage when used to process a low-k material. Additionally, although this technique is advantageous in faster dicing of wafers into small chips, high dicing accuracy and less sidewall roughness of the resulting chips, it involves a complex, costly process, requires the use of photoresist as a protective medium during dicing, and cannot dice wafers with metal in dicing lanes. Laser dicing utilizes nanosecond to femtosecond lasers to dice wafers along dicing lanes. This technique has no selectivity for materials to be diced, but generates undesirable heat during dicing and suffers from high sidewall roughness of the resulting chips and accumulation of slag on chip surfaces. Stealth dicing focuses infrared (IR) laser radiation inside a semiconductor structure being processed to destroy its lattice and generate stress therein. After that, the semiconductor structure can be separated into individual chips simply by stretching the dicing tape. Despite the advantages of less invasiveness and less chip contamination, this technique is associated with a number of problems when used to dice a wafer with metal in dicing lanes, including notching, cracking, passivation and metal layer delamination and buckling. Therefore, each of these dicing techniques has a number of limitations, and none of them could provide extremely desirable performance without being modified.

In-depth studies conducted by the inventors reveal that extremely desirable dicing performance can be achieved when a stealth dicing process is used to dice a modified semiconductor structure with metal-free blank regions. These blank regions can be modified in the stealth dicing process so that the semiconductor structure can be separated into individual chips simply by applying an external force thereto. In this way, the advantages of the stealth dicing technique can be leveraged while effectively circumventing its disadvantages to achieve extremely desirable dicing of the semiconductor structure.

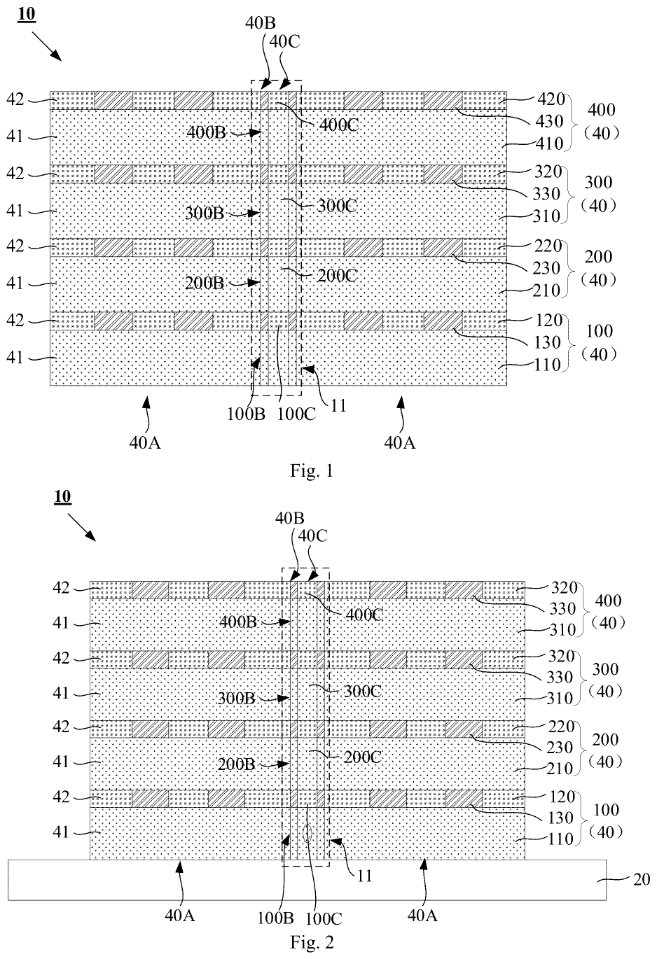

Referring to FIGS. 1 to 5, the semiconductor structure 10 includes at least two substrates 40 each including a backing layer 41 and a dielectric layer 42 on the backing layer 41. The semiconductor structure 10 has metal-free blank regions 11, and at least two of the backing layers 41 in the blank regions 11 have been modified with laser radiation. In each adjacent pair of laser-modified backing layers 41, the two layers are spaced apart by one or more of the dielectric layers 42. Specifically, the laser-modified backing layers 41 may be spaced apart by one or more of the dielectric layers 42, and optionally by one or more of the backing layers 41 not modified with laser radiation. In one embodiment, each backing layer in the blank regions 11 has been modified with laser radiation. In this case, adjacent modified layers are spaced apart by the dielectric layers 42. According to embodiments of the present application, the dielectric layers 42 are not modified with laser radiation.

The semiconductor structure 10 may include two, three, four, five, six or another number of substrates, and the present application is not limited to any particular number of substrates in the semiconductor structure 10. Preferably, the number of substrates in the semiconductor structure 10 ranges from 2 to 16. The semiconductor structure 10 has a thickness between 10 μm and 400 μm, which can ensure functionality, quality and reliability of the semiconductor structure 10 and facilitate reliable performance of the subsequent dicing process.

Each substrate 40 may be of the same materials or structure, or not. Examples of a material, from which the backing layer 41 in each substrate 40 is fabricated, may include semiconductor materials, such as silicon and germanium, and non-semiconductor materials. Examples of a material, from which the dielectric layer 42 in each substrate 40 is fabricated, may include oxides, nitrides and other dielectric materials well known in the art.

Each substrate 40 may have device regions 40A and dicing lanes 40B between the device regions 40A. The dicing lanes 40B in each substrate 40 contain blank sub-regions 40C. Projections of the blank sub-regions 40C of the substrates 40 on one of the substrates 40 have an overlap, and portions of the blank sub-regions 40C of the substrates 40 corresponding to the overlap provide the blank regions 11 of the semiconductor structure 10.

The following embodiments are described in the context of four substrates being included as an example, namely, a first substrate 100, a second substrate 200, a third substrate 300 and a fourth substrate 400. FIG. 1 is a schematic illustration of the semiconductor structure according to one embodiment of the present invention.

As shown in FIG. 1, according to embodiments of the present application, the semiconductor structure 10 includes a first substrate 100, a second substrate 200, a third substrate 300 and a fourth substrate 400. The first substrate 100 includes a first backing layer 110, a first dielectric layer 120 on the first backing layer 110 and a first conductive layer 130 in the first dielectric layer 120. The first substrate 100 has first device regions 100A and first dicing lanes 100B between adjacent device regions 100A. The first dicing lanes 100B contain metal-free first blank sub-regions 100C. The second substrate 200 resides on the first substrate 100 and includes a second backing layer 210, a second dielectric layer 220 on the second backing layer 210 and a second conductive layer 230 in the second dielectric layer 220. The second substrate 200 has second device regions 200A and second dicing lanes 200B between adjacent second device regions 200A. The second dicing lanes 200B contain metal-free second blank sub-regions 200C. The third substrate 300 resides on the second substrate 200 and includes a third backing layer 310, a third dielectric layer 320 on the third backing layer 310 and a third conductive layer 330 in the third dielectric layer 320. The third substrate 300 has third device regions 300A and third dicing lanes 300B between adjacent third device regions 300A. The third dicing lanes 300B contain metal-free third blank sub-regions 300C. The fourth substrate 400 resides on the third substrate 300 and includes a fourth backing layer 410, a fourth dielectric layer 420 on the fourth backing layer 410 and a fourth conductive layer 430 in the fourth dielectric layer 420. The fourth substrate 400 has fourth device regions 400A and fourth dicing lanes 400B between adjacent fourth device regions 400A. The fourth dicing lanes 400B contain metal-free fourth blank sub-regions 400C.

The first substrate 100, the second substrate 200, the third substrate 300 and the fourth substrate 400 are sequentially stacked, with one or more pairs of adjacent substrate being bonded together and/or one or more pairs of adjacent substrate not being bonded together. Examples of a suitable bonding method may include, among others, hybrid bonding, fusion bonding, temporary bonding and bump bonding. A front or back side of the first substrate 100 may be contact a front or back side of the second substrate 200. For example, the first backing layer 110 and the second backing layer 210 are spaced apart by the first dielectric layer 120, or by the second dielectric layer 220, or by both. The side of the second substrate 200 away from the first substrate 100 contacts a front or back side of the third substrate 300.

As shown in FIG. 1, according to embodiments of the present application, the first substrate 100, the second substrate 200, the third substrate 300 and the fourth substrate 400 are sequentially bonded together in a direction (vertical, as shown) in which projections of the first blank sub-regions 100C, the second blank sub-regions 200C, the third blank sub-regions 300C and the fourth blank sub-regions 400C on the first substrate 100, the second substrate 200, the third substrate 300 or the fourth substrate 400 have an overlap. Portions of the first blank sub-regions 100C, the second blank sub-regions 200C, the third blank sub-regions 300C and the fourth blank sub-regions 400C corresponding to the overlap provide the blank regions 11 of the semiconductor structure 10. In one embodiment, the projections of the first blank sub-regions 100C, the second blank sub-regions 200C, the third blank sub-regions 300C and the fourth blank sub-regions 400C on the first substrate 100 exactly coincide. That is, the first blank sub-regions 100C, the second blank sub-regions 200C, the third blank sub-regions 300C and the fourth blank sub-regions 400C are equally sized and exactly aligned. In another embodiment, the projections of the first blank sub-regions 100C, the second blank sub-regions 200C, the third blank sub-regions 300C and the fourth blank sub-regions 400C on the first substrate 100 partially overlap. That is, at least one of the first blank sub-regions 100C, the second blank sub-regions 200C, the third blank sub-regions 300C and the fourth blank sub-regions 400C is not equally sized or exactly aligned with the others. For example, the second blank sub-regions 200C are wider than the first blank sub-regions 100C, and in the direction of bonding, the projections of the second blank sub-regions 200C on the first substrate 100 encompass not only the entire first blank sub-regions 100C but also part of the first substrate 100 outside the first blank sub-regions 100C. As another example, the second blank sub-regions 200C are as wide as the first blank sub-regions 100C, and in the direction of bonding, the projections of the second blank sub-regions 200C on the first substrate 100 encompass part of the first blank sub-regions 100C and part of the first substrate 100 outside the first blank sub-regions 100C.

Preferably, the first dicing lanes 100B, the second dicing lanes 200B, the third dicing lanes 300B and the fourth dicing lanes 400B have a width between 10 μm and 100 μm. The first blank sub-regions 100C, the second blank sub-regions 200C, the third blank sub-regions 300C and the fourth blank sub-regions 400C have a width between 0.5 μm and 100 μm. For example, the width of the first dicing lanes 100B is 80 μm, and the width of the first blank sub-regions 100C is 60 μm; the width of the second dicing lanes 200B is 80 μm, and the width of the second blank sub-regions 200C is 80 μm; the width of the third dicing lanes 300B is 80 μm, and the width of the third blank sub-regions 300C is 80 μm; and the width of the fourth dicing lanes 400B is 80 μm, and the width of the fourth blank sub-regions 400C is 70 μm. As another example, the width of the first dicing lanes 100B is 100 μm, and the width of the first blank sub-regions 100C is 70 μm; the width of the second dicing lanes 200B is 90 μm, and the width of the second blank sub-regions 200C is 70 μm; the width of the third dicing lanes 300B is 80 μm, and the width of the third blank sub-regions 300C is 70 μm; and the width of the fourth dicing lanes 400B is 90 μm, and the width of the fourth blank sub-regions 400C is 70 μm.

Preferably, in the widthwise direction of the first dicing lanes 100B, the first blank sub-regions 100C lie in the middle of the first dicing lanes 100B; in the widthwise direction of the second dicing lanes 200B, the second blank sub-regions 200C lie in the middle of the second dicing lanes 200B; in the widthwise direction of the third dicing lanes 300B, the third blank sub-regions 300C lie in the middle of the third dicing lanes 300B; and in the widthwise direction of the fourth dicing lanes 400B, the fourth blank sub-regions 400C lie in the middle of the fourth dicing lanes 400B. With this arrangement, at least part of the fourth blank sub-regions 400C, at least part of the third blank sub-regions 300C and at least part of the second blank sub-regions 200C will at least partially overlap the first blank regions 100C. In addition, this provides a larger process window for subsequent processes and facilitates the performance of the subsequent dicing process.

A stealth laser dicing process is performed on the backing layers 41 of the substrates 40 in the blank regions 11 to modify at least one of them. The backing layer 41 of each substrate 40 in the blank regions 11 may be modified. According to embodiments of the present application, the first backing layer 110, the second backing layer 210, the third backing layer 310 and the fourth backing layer 410 in the blank regions 11 is modified in the stealth laser dicing process. As a result, first modified portions are formed in the first backing layer 110, second modified portions in the second backing layer 210, third modified portions in the third backing layer 310, and fourth modified portions in the fourth backing layer 410. Stealth laser dicing involves mainly focusing a pulsed laser beam within a material through its surface to modify its properties or composition so that the irradiated material can be separated simply by applying an external force thereto. As stealth laser dicing does nothing with dielectric materials, as a result of the dicing process, in each adjacent pair of laser-modified backing layers, the two layers are spaced apart by one or more of the unmodified dielectric layers 42. For example, the first backing layer 110 in the first blank sub-regions 100C and the second backing layer 210 in the second blank sub-regions 200C may be modified with laser radiation. As a result, the laser-modified first and second backing layers 110, 210 may be spaced apart by the unmodified first dielectric layer 120, or by the unmodified second dielectric layer 220, or by both.

Further, an external force is applied to the semiconductor structure 10 perpendicular to and away from the blank regions 11 to separate each modified backing layer 41 in the substrate 40 at the modified portions. For example, the first backing layer 110 is separated at the first modified portions, the second backing layer 210 at the second modified portions, the third backing layer 310 at the third modified portions, and the fourth backing layer 410 at the fourth modified portions. At the same time, each dielectric layer 42 between adjacent laser-modified backing layers 41 is also separated at both sides. For example, when the unmodified first dielectric layer 120 is sandwiched by the first backing layer 110 and the second backing layer 210, it may be separated at both the side in contact with the first backing layer 110 and the side in contact with the second backing layer 210. When the unmodified second dielectric layer 220 is sandwiched by the second backing layer 210 and the third backing layer 310, it may be separated at both the side in contact with the second backing layer 210 and the side in contact with the third backing layer 310. In this way, the semiconductor structure 10 can be separated into individual devices. When the semiconductor structure 10 is a wafer stack, it can be separated into individual chip stacks. For example, the semiconductor structure 10 may be a stack of 8 wafers and can be separated into chip stacks each consisting of 8 stacked chips.

According to embodiments of the present application, since the blank regions 11 of the semiconductor structure 10 are metal-free, extremely desirable dicing performance can be achieved by a stealth dicing process performed on the blank regions 11.

Further, reference is now made to FIGS. 2 to 7, which are schematic diagrams of structures resulting from steps in a method of dicing a semiconductor structure according to an embodiment of the present invention.

As shown in FIG. 2, the semiconductor structure 10 is provided, which includes at least two substrates 40 each including a backing layer 41 and a dielectric layer 42 on the backing layer 41. The semiconductor structure 10 has metal-free blank regions 11. According to embodiments of the present application, the semiconductor structure 10 includes a first substrate 100, a second substrate 200 bonded to the first substrate 100, a third substrate 300 bonded to the second substrate 200 and a fourth substrate 400 bonded to the third substrate 300. That is, the semiconductor structure 10 includes four substrates 40.

According to embodiments of the present application, the semiconductor structure 10 is then attached to a carrier tape 20, facilitating the performance of subsequent process.

Next, a stealth laser dicing process is performed to modify at least two of the backing layers 41 of the substrates 40 in the blank regions 11 with laser radiation.

As shown in FIG. 2, according to embodiments of the present application, in the stealth dicing process, first blank sub-regions 100C of the first substrate 100 are first modified. The first blank regions 100C may be overlapped and aligned with second blank sub-regions 200C, third blank sub-regions 300C and fourth blank sub-regions 400C. Specifically, the first blank regions 100C may be modified by irradiating laser radiation thereon.

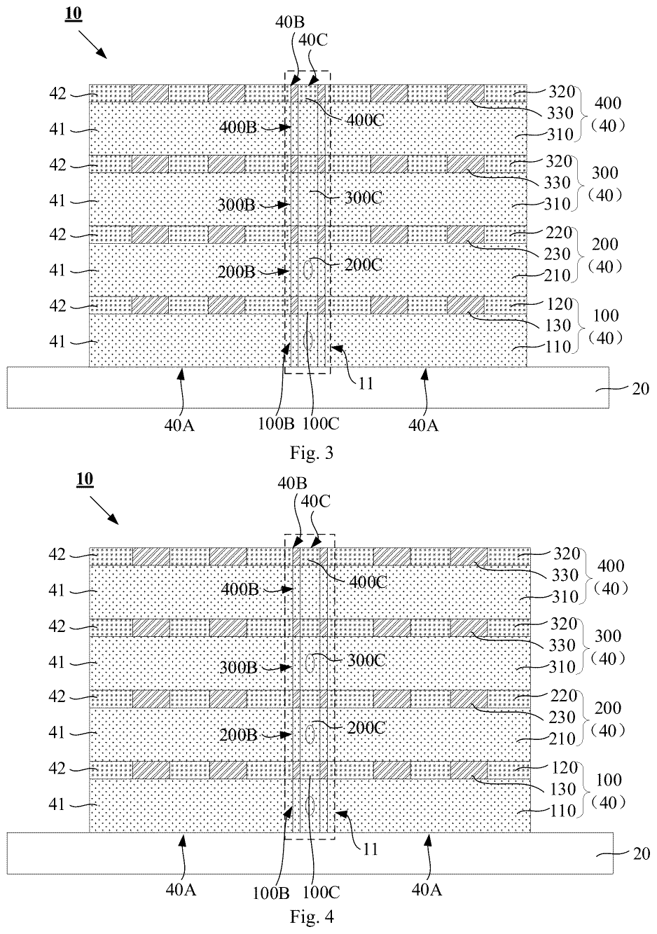

Subsequently, as shown in FIG. 3, the second blank sub-regions 200C of the second substrate 200 are modified in the stealth dicing process.

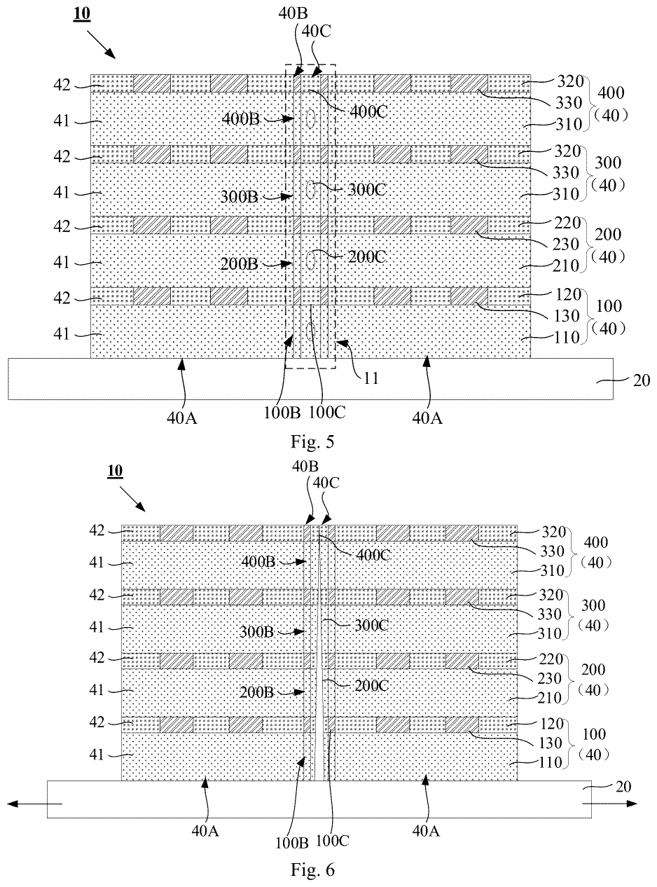

Afterwards, as shown in FIGS. 4 and 5, the third blank sub-regions 300C of the third substrate 300 and then the fourth blank sub-regions 400C of the fourth substrate 400 are modified in the stealth dicing process.

That is, the blank regions 11 of the semiconductor structure 10 are successively modified in the stealth dicing processes. That is, the first blank sub-regions 100C, then the second blank sub-regions 200C, then the third blank sub-regions 300C and then the fourth blank sub-regions 400C are modified. According to embodiments of the present application, in each adjacent pair of laser-modified backing layers 41, the two layers are spaced apart by one of the dielectric layers 42.

In alternative embodiments, in the stealth dicing process, the blank regions 11 of the semiconductor structure 10 may also be selectively modified. That is, the present invention is not limited to any particular number of first blank sub-regions 100C, second blank sub-regions 200C, third blank sub-regions 300C or fourth blank sub-regions 400C, which are modified, or to any particular order, in which they are modified. For example, in one embodiment of the present application, only the first blank sub-regions 100C and the fourth blank sub-regions 400C are modified. In this case, the adjacent laser-modified backing layers 41 may be spaced apart by one or more dielectric layers 42 and one or more unmodified backing layers 41.

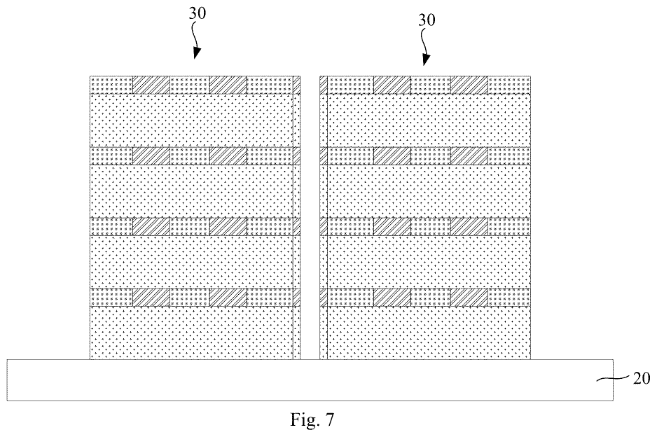

After that, as shown in FIGS. 6 and 7, an external force is applied to the semiconductor structure 10 to separate it into individual devices (here, individual chips 30). According to particular embodiments of the present application, the external force may be directly applied to the carrier tape 20 to stretch it. In this way, the external force still acts on the semiconductor structure 10 to separate it into individual chips 30.

Specifically, under the action of the external force, each modified backing layer 41 in the substrate 40 is separated, and each dielectric layer 42 between adjacent laser-modified backing layers 41 is also separated at both sides. As a result, the semiconductor structure 41 is separated into individual devices (here, individual chips 30).

According to embodiments of the present application, in the stealth dicing process, the blank regions of the semiconductor structure 10 are modified so that the structure (here, lattice) of the semiconductor structure 10 is destroyed, giving rise to stress. Thus, the semiconductor structure 10 can be separated with high quality into individual chips 30 by applying an external force thereto, in particular by stretching the carrier tape 20. According to embodiments of the present application, the advantages of less invasiveness and less chip contamination of the stealth dicing technique can be leveraged to achieve extremely desirable dicing performance.

As used herein, any reference to “one embodiment” or “some embodiments” means that a particular feature, structure, or characteristic described in connection with the embodiment is included in at least one embodiment or at least some embodiments disclosed herein. Therefore, the appearances of the phrase “in one embodiment” or “in some embodiments” in various places in the specification are not necessarily all referring to the same one or some embodiments. Further, in one or more embodiments, features, structures or characteristics may be combined in any suitable combination and/or sub-combination.

While a few particular embodiments of the present application have been described in detail by way of examples, those skilled in the art will understand that the foregoing examples are provided for illustration only rather than any limitation on the scope of the application. The various embodiments disclosed herein can be combined in any combination, without departing from the spirit and scope of the application. Those skilled in the art will also understand that various modifications can be made to the embodiments, without departing from the scope and spirit of the application. The scope of the application is defined by the appended claims.

What is claimed is:

1. A semiconductor structure, comprising:
at least two substrates each comprising a backing layer and a dielectric layer on the backing layer, wherein the semiconductor structure has blank regions, the blank regions do not include metal, in the blank regions, at least two of the backing layers have been modified with laser radiation, and wherein each adjacent two of laser-modified backing layers are spaced apart by the dielectric layer.

2. The semiconductor structure of claim 1, wherein the dielectric layers are not modified with laser radiation.

3. The semiconductor structure of claim 1, wherein each of the at least two substrates has device regions and dicing lanes between the device regions, the dicing lanes comprising blank sub-regions, wherein projections of the blank sub-regions on one of the at least two substrates have an overlap, and portions of the blank sub-regions of the at least two substrates corresponding to the overlap provide the blank regions of the semiconductor structure.

4. The semiconductor structure of claim 3, wherein the dicing lanes of each substrate have a width between 10 μm and 100 μm.

5. The semiconductor structure of claim 4, wherein the blank regions have a width between 0.5 μm and 100 μm.

6. The semiconductor structure of claim 1, wherein the semiconductor structure is a wafer stack separable into chip stacks.

7. The semiconductor structure of claim 1, wherein the number of the substrates in the semiconductor structure ranges from 2 to 16.

8. The semiconductor structure of claim 1, wherein the semiconductor structure has a thickness between 10 μm and 400 μm.

9. The semiconductor structure of claim 1, wherein the semiconductor structure includes a first substrate, a second substrate, a third substrate and a fourth substrate which are sequentially stacked, the first substrate comprising a first backing layer and a first dielectric layer on the first backing layer, the second substrate comprising a second backing layer and a second dielectric layer on the second backing layer, the third substrate comprising a third backing layer and a third dielectric layer on the third backing layer, the fourth substrate comprising a fourth backing layer and a fourth dielectric layer on the fourth backing layer.

10. The semiconductor structure of claim 9, wherein the first backing layer and the second backing layer are spaced apart by the first dielectric layer.

11. The semiconductor structure of claim 9, wherein the first backing layer and the second backing layer are spaced apart by the second dielectric layer.

12. The semiconductor structure of claim 9, wherein the first backing layer and the second backing layer are spaced apart by both of the first dielectric layer and the second dielectric layer.

13. The semiconductor structure of claim 9, wherein the first substrate has first device regions and first dicing lanes between adjacent first device regions, the first dicing lanes contain first blank sub-regions that do not include metal; the second substrate has second device regions and second dicing lanes between adjacent second device regions, the second dicing lanes contain second blank sub-regions that do not include metal; the third substrate has third device regions and third dicing lanes between adjacent third device regions, the third dicing lanes contain third blank sub-regions that do not include metal; the fourth substrate has fourth device regions and fourth dicing lanes between adjacent fourth device regions, the fourth dicing lanes contain fourth blank sub-regions that do not include metal; the first substrate, the second substrate, the third substrate and the fourth substrate are sequentially bonded together in a direction in which projections of the first blank sub-regions, the second blank sub-regions, the third blank sub-regions and the fourth blank sub-regions on the first substrate, the second substrate, the third substrate or the fourth substrate have an overlap.

14. The semiconductor structure of claim 13, wherein the projections of the first blank sub-regions, the second blank sub-regions, the third blank sub-regions and the fourth blank sub-regions on the first substrate exactly coincide.

15. The semiconductor structure of claim 13, wherein the projections of the first blank sub-regions, the second blank sub-regions, the third blank sub-regions and the fourth blank sub-regions on the first substrate partially overlap.

16. The semiconductor structure of claim 13, wherein the second blank sub-regions are as wide as the first blank sub-regions, and in the direction of bonding, the projections of the second blank sub-regions on the first substrate encompass part of the first blank sub-regions and part of the first substrate outside the first blank sub-regions.

17. A method of dicing a semiconductor structure, the method comprising:
providing a semiconductor structure comprising at least two substrates each comprising a backing layer and a dielectric layer on the backing layer, the semiconductor structure having blank regions, the blank regions do not include metal; and
performing a stealth laser dicing process to modify at least two of the backing layers of the at least two substrates in the blank regions with laser radiation, wherein each adjacent two of laser-modified backing layers are spaced apart by the dielectric layer.

18. The method of claim 17, wherein after the backing layer in the blank regions of each of the at least two substrates is modified in the stealth laser dicing process, the method further comprising separating the semiconductor structure into individual devices by applying an external force to the semiconductor structure.

19. The method of claim 18, wherein separating the semiconductor structure into the individual devices by applying the external force to the semiconductor structure comprises: under the action of the external force, separating each laser-modified backing layer of the substrate at its modified portions and separating each dielectric layer between adjacent laser-modified backing layers at both sides, resulting in the separation of the semiconductor structure into the individual devices.

20. The method of claim 17, further comprising:
before the backing layer in the blank regions of each of the at least two substrates is modified in the stealth laser dicing process, placing the semiconductor structure on a carrier tape; and
after the backing layer in the blank regions of each of the at least two substrates is modified in the stealth laser dicing process, stretching the carrier tape to apply the external force to the semiconductor structure.
